(19) United States
(12) Patent Application Publication
(10) Pub. No.: US 2025/0331343 A1
(43) Pub. Date: Oct. 23, 2025

(54) DISPLAY MODULE AND LED BEAD

(71) Applicant: SHENZHEN LINGCAN TECHNOLOGY CO., LTD., Shenzhen (CN)

(72) Inventors: RENKAI WANG, Shenzhen (CN); XIAOPING YAN, Shenzhen (CN)

(21) Appl. No.: 18/893,529

(22) Filed: Sep. 23, 2024

(30) Foreign Application Priority Data
Apr. 18, 2024 (CN) 202420821969.4

(51) Int. Cl. H01L 33/62; H01L 25/075

(52) U.S. Cl. CPC H10H 20/857; H01L 25/0753

(57) ABSTRACT

A display module and a lamp bead are provided, the display module includes a lamp bead main body, the lamp bead main body is provided with at least two anode solder pads and at least three light emitting chips, an anode of one of the light emitting chips is electrically connected to one of the anode solder pads, and anodes of at least two other light emitting chips are electrically connected to another of the anode solder pads; a mask is provided at an outside of the lamp bead main body, a gap is formed between the mask and the lamp bead main body. The gap includes an inclined section, and the inclined section extends obliquely from a light emitting surface of the lamp bead main body towards a direction away from the light emitting surface and away from the lamp bead main body.

### CROSS-REFERENCE TO RELATED APPLICATIONS

This application claims priority to Chinese Patent Application No. 202420821969.4, filed on Apr. 18, 2024, which is hereby incorporated by reference in its entirety.

### TECHNICAL FIELD

The present disclosure relates to the field of LED display technologies, and in particular, to a display module and a LED bead.

### BACKGROUND

At present, LED lighting has penetrated into various scenarios where people need light for their daily lives and residences. With this, there is an increasing demand for a quality of LED light sources, as well as a continuous improvement in product reliability and lifespan.

In related technologies, LED display screens generally use LED beads, especially RGB beads. Currently, in a conventional co-anode RGB beads on the market (as shown in a circuit structure in FIG. 1), a voltage requirement for red a LED chip is around 2.8V, while the voltage requirement for green and blue LED chips is around 3.8V. Due to a structural design reason, the co-anode technology LED display screen usually supplies power to RGB tri-color chips with a voltage higher than 3.8V uniformly, thereby resulting in high power loss. As the red LED chip only requires a voltage of 2.8V, a uniform voltage of 3.8V will result in excess loss, which will be dissipated in a form of heat.

Therefore, it is necessary to design a new display module and a LED chip to overcome the above problems.

### SUMMARY

The present application provides a display module and a LED bead that can solve the technical problem of high-power loss in related technologies.

In a first aspect, some embodiments of the present application provides a display module including: a lamp bead main body, which is provided with at least two anode solder pads and at least three light-emitting chips, where an anode of one of the light-emitting chips is electrically connected to one of the anode solder pads, and anodes of at least two other light-emitting chips are electrically connected to another of the anode solder pads; a mask, which is provided at an outside of the lamp bead main body, a gap is formed between the mask and the lamp bead main body, the gap includes an inclined section, and the inclined section extends obliquely from a light emitting surface of the lamp bead main body towards a direction away from the light emitting surface and away from the lamp bead main body.

Combining the first aspect, in one embodiment, the at least three light-emitting chips include a red-light chip, a blue-light chip, and a green-light chip; an anode of the red-light chip is electrically connected to one of the anode solder pads; anodes of the blue-light chip and the green-light chip are electrically connected to another of the anode solder pad.

Combining the first aspect, in one embodiment, the lamp bead main body is provided with two anode solder pads and three light-emitting chips; the lamp bead main body is further provided with two anode pins and three cathode pins; each of the anode solder pads is electrically connected to one of the anode pins, and a cathode of each of the light-emitting chips is electrically connected to one of the cathode pins.

Combining the first aspect, in one embodiment, the lamp bead main body is further provided with a dummy pin, the dummy pin with the two anode pins and the three cathode pins are symmetrically distributed on the lamp bead main body.

Combining the first aspect, in one embodiment, the gap is filled with a colloform, and at least a part of the inclined section is not filled with the colloform, thereby a clearance is formed between the colloform in the gap and the light emitting surface.

Combining the first aspect, in one embodiment, a first inclined surface is formed at an outside of the lamp bead main body, and a second inclined surface is formed inside the mask; the second inclined surface has a same inclination direction as the first inclined surface, and the inclined section is formed between the first inclined surface and the second inclined surface.

Combining the first aspect, in one embodiment, the first inclined surface is arranged parallel to the second inclined surface.

Combining the first aspect, in one embodiment, the gap further includes a vertical section connected to the inclined section, and relative to the inclined section, the vertical section is biased away from the light emitting surface.

Combining the first aspect, in one embodiment, the vertical section is filled with the colloform, and at least a part of the colloform extends into the inclined section.

In a second aspect, the present embodiment provides a lamp bead including: a lamp bead main body, which is provided with at least two anode solder pads and at least three light-emitting chips, where an anode of one of the light-emitting chips is electrically connected to one of the anode solder pads, and anodes of at least two other light-emitting chips are electrically connected to another of the anode solder pads.

In a third aspect, the present embodiment provides a display module including a plurality of lamp beads.

The beneficial effects brought by the technical solution provided in embodiments of the present application include:
by electrically connecting the anodes of light-emitting chips with consistent voltage requirements to a same anode solder pad and connecting the anodes of light-emitting chips with different voltage requirements to different anode solder pads, separate power supply for light-emitting chips with different voltage requirements can be achieved, which can reduce a power loss and solve a technical problem of high-power loss in related technologies. And the gap between the mask and the lamp bead main body is configured to be extended obliquely. When viewed in a direction perpendicular to a light emitting surface (i.e. from the front), a structure displayed in the gap is an outer surface of the lamp bead main body, rather than the complete gap, which can improve a front contrast and display effect, solving a technical problem of a vertical gap reducing the front contrast and display effect in related technologies.

### BRIEF DESCRIPTION OF DRAWINGS

In order to provide a clearer explanation of the technical solution in the embodiments of the present application, a brief introduction will be given to the drawings required for the description of the embodiments. It is obvious that the drawings described below are only some embodiments of the present application. For those skilled in the art, other drawings can be obtained based on these drawings without creative work.

FIG. 1 shows a circuit structure diagram of a conventional co-anode RGB LED bead in related technology.

FIG. 2 is a schematic top view of a lamp bead provided in an embodiment of the present application.

FIG. 3 is a schematic sectional view of a display module provided in an embodiment of the present application.

FIG. 4 is a schematic structural diagram of a solder pad on a lamp bead main body provided in an embodiment of the present application.

FIG. 5 is a schematic structural diagram of a pin on the lamp bead main body provided in an embodiment of the present application.

FIG. 6 shows a circuit connection structure diagram of a light-emitting chip provided in an embodiment of the present application.

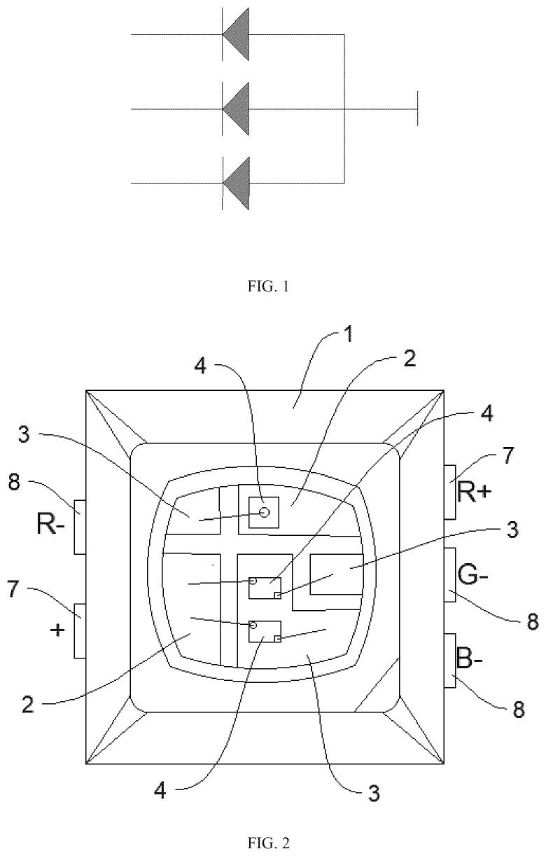

Numeral reference: 1. lamp bead main body; 11. light emitting surface; 12. first

inclined surface; 2. anode solder pad; 3. cathode pad; 4. light-emitting chip; 5. mask; 51. second inclined surface; 6. gap; 61. inclined section; 62. vertical section; 7. anode pin; 8. cathode pin; 9. colloform.

### DESCRIPTION OF EMBODIMENTS

In order to enable those skilled in the art to better understand the technical solution of the present application, the following will provide a clear and complete description of the technical solution in the embodiments of the present application in combination with the accompanying drawings. Obviously, the described embodiments are only a part of the embodiments of the present application, not all of them. Based on the embodiments in the present application, all other embodiments obtained by those skilled in the art without creative work are within the protection scope of the present application.

Embodiments of the present application provide a display module and a LED bead that can solve a technical problem of high-power loss and reduced a front contrast and a display effect due to a vertical gap in related technologies.

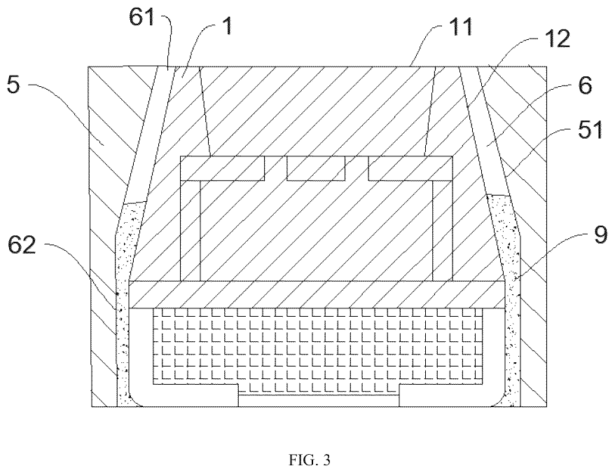

As shown in FIG. 2, there is a display module provided in an embodiment of the present application, which may include: a lamp bead main body 1, the lamp bead main body 1 is provided with at least two anode solder pads 2, and the lamp bead main body 1 is installed with at least three light-emitting chips 4, where an anode of one of the light-emitting chips 4 is electrically connected to one of the anode solder pads 2, and anodes of at least two other light-emitting chips 4 are electrically connected to another of the anode solder pads 2; a mask 5, provided at an outside of the lamp bead main body 1; and a gap 6 formed between the mask 5 and the lamp bead main body 1 (see FIG. 3). The gap 6 includes an inclined section 61, and the inclined section 61 extends obliquely from a light emitting surface 11 of the lamp bead main body 1 towards a direction away from the light emitting surface 11 and away from the lamp bead main body 1. Where, the light emitting surface 11 is an upper surface of the lamp bead main body 1, and the inclined section 61 here can be understood as extending downwards from the upper surface of the lamp bead main body 1 and expanded outwardly. When viewed from bottom to top, that is, the lamp bead main body 1 is configured to be a narrow cup mouth, and the gap 6 gradually shrinks from bottom to top towards a center of the lamp bead main body 1. In this embodiment, the lamp bead main body 1 and components on the lamp bead main body 1 are combined to form the lamp bead, and the gap 6 is formed between the lamp bead and the mask 5.

In this embodiment, when the lamp bead main body 1 is provided with three light-emitting chips 4, two anode solder pads 2 can be provided with. When there are more than three light-emitting chips 4 on the lamp bead main body 1, the number of the anode solder pads 2 can be appropriately increased according to a demand. There is no limit to the number of the light-emitting chips 4 and the anode solder pads 2 here, and adjacent two anode solder pads 2 are spaced apart from each other. Both the lamp bead main body 1 and the mask 5 can be injection molded using injection molds, and both the lamp bead main body 1 and the mask 5 can be made in black to enhance contrast.

This embodiment achieves separate power supply for the light-emitting chips 4 with different voltage requirements by electrically connecting the anodes of the light-emitting chips 4 with consistent voltage requirements to a same anode solder pad 2. For example, anodes of a blue-light chip and a green-light chip can be electrically connected to the same anode solder pad 2, while the anodes of the light-emitting chips 4 with different voltage requirements can be electrically connected to different anode solder pads 2. For example, an anode of the red-light chip can be electrically connected to another anode solder pad 2, so that R/GB chips can be electrically connected to different anode solder pads 2. This can provide a voltage of 2.8V for the red-light chip and 3.8V for the blue-green chip, and there will be no excess voltage loss for the red-light chip, which can reduce a power loss and solve a technical problem of large power loss in related technologies.

In related technologies, the mask is required at the outside of the LED lamp bead on an application end. Due to a need for sealing glue between the mask and the LED lamp bead, the mask cannot be well adhered to the LED lamp bead, resulting in a vertical gap between the two. The vertical gap directly affects a product effect, reduces a front contrast, weakens a display effect, and affects a user experience. In this embodiment, the gap 6 between the mask 5 and the lamp bead main body 1 is configured to extend obliquely. An opening of the gap 6 on the light emitting surface 11 is closer to a center of the lamp bead main body 1. When viewed in a direction perpendicular to the light emitting surface 11 (i.e. from the front), a structure displayed in the opening of the gap 6 is an outer surface of the lamp bead main body 1, rather than a complete bottom surface of the gap 6. When viewed from a sight line, the outer surface of the lamp bead is in a completely black state of the lamp bead main body 1, which can improve the front contrast and display effect, and solve the technical problem of the vertical gap reducing the front contrast and display effect in related technologies.

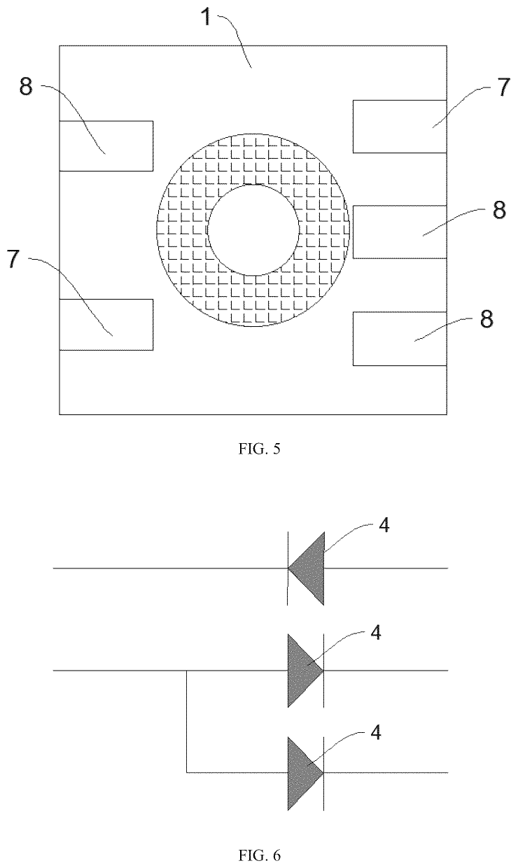

As shown in FIG. 2, in one embodiment, at least three light-emitting chips 4 include a red-light chip, a blue-light chip, and a green-light chip. An anode of the red-light chip is electrically connected to one of the anode solder pads 2; anodes of the blue-light chip and the green-light chip are electrically connected to another of the anode solder pads 2. In this embodiment, in an implementation mode, the three light-emitting chips 4 are set to the red, blue, and green-light chips respectively, and the anode of the red-light chip is separately connected to one of the anode solder pads 2. The anodes of the blue-light chip and the green-light chip are jointly connected to one of the anode solder pads 2. The blue-light chip and the green-light chip are designed to be co-anode (as shown in a circuit structure in FIG. 6), which can provide a voltage of 3.8V at the same time. The red-light chip is powered by 2.8V separately, so there is no energy loss, and the red-light chip and the blue-green chip are powered separately.

Furthermore, as there are many rental channels for outdoor product usage scenarios, there may be collisions during transportation and splicing of a display module, which can cause the lamp bead to be fallen off. Therefore, increasing a push force of the lamp bead is also necessary. As shown in FIG. 2, in one embodiment, the lamp bead main body 1 is provided with two anode solder pads 2 and three light-emitting chips 4. As shown in FIG. 5, the lamp bead main body 1 is further provided with two anode pins 7 and three cathode pins 8. Each anode solder pad 2 is electrically connected to one of the anode pins 7, and a cathode of each light-emitting chip 4 is electrically connected to one of the cathode pins 8. Where, the anode pins 7 and the cathode pins 8 can be provided on a rear of the lamp bead main body 1 so as to form a five-pin structure on the lamp bead main body 1, which separates the red light and blue-green light power supply and can reduce a defect of red light energy loss in the co-anode design; at the same time, the related technology adopts a co-anode design of three chips, red, green, and blue, with a pin count of 4 and a 4-pin area of 1 square millimeter. In this embodiment, under a same size of the lamp bead (this solution is generally applicable to a small-sized lamp bead, i.e. 2 mm * 2 mm), the number of pins is changed to five, and a 5-pin area is 1.098 square millimeters. Therefore, adding an additional pin can increase a soldering thrust by more than 10%, which not only adapts to a separate power supply mode, but also further enhances the thrust of the lamp bead. And this embodiment is designed with the five-pins to enable the chip to accurately identify the pins, rendering it easy to quickly and accurately identify a corresponding pin. Considering a cost and chip issues, in an implementation mode, the pins on the lamp bead main body 1 is five-pins, provided that the five-pins can be powered separately.

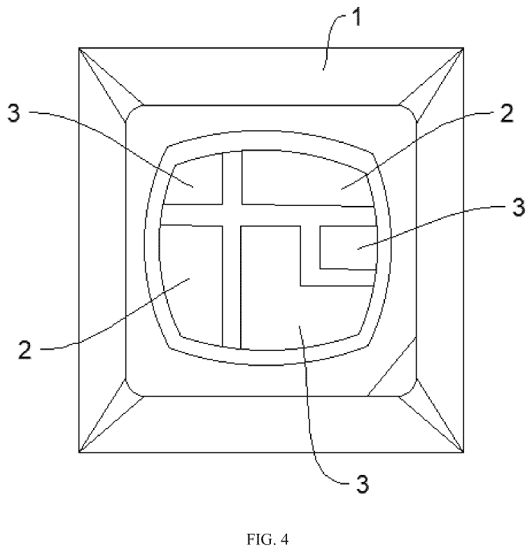

On the basis of the above technical solution, as shown in FIG. 4, the lamp bead main body 1 can also be provided with three cathode pads 3. The cathodes of the red, green, and blue light-emitting chips 4 are respectively electrically connected to the three cathode pads 3, and each of the cathode pads 3 is electrically connected to one of the cathode pins 8. The cathode pads 3 and the cathode pins 8 are in a one-to-one correspondence.

In an implementation mode, the lamp bead main body 1 may also be provided with a dummy pin, the dummy pin with the two anode pins 7 and the three cathode pins 8 are symmetrically distributed on the lamp bead main body 1. In this embodiment, to achieve separate lighting of different light-emitting chips 4, at least a five-pin structure is provided with, namely two anode pins 7 and three cathode pins 8. Considering a symmetry of the pins, one dummy pin can also be added to the lamp bead main body 1 so as to form a six-pin structure.

As shown in FIG. 3, in one embodiment, the gap 6 can be filled with a colloform 9 (i.e. sealing glue), which can firmly connect the lamp bead main body 1 and the mask 5 together, and at least a part of the inclined section 61 is not filled with colloform 9, thereby forming a clearance between the colloform 9 in the gap 6 and the light emitting surface 11. That is to say, in this embodiment, although the gap 6 is filled with the colloform 9, the colloform 9 does not fill the gap 6 completely. A lower part of the gap 6 is filled with the colloform 9, and an upper part thereof is empty. This ensures a connection between the lamp bead main body 1 and the mask 5, and also ensures that there is no colloform 9 filling at a position near the light-emitting surface. The lamp bead main body 1 with a black surrounding will not affect a light output effect of the light-emitting chip 4.

As shown in FIG. 3, in some embodiments, a first inclined surface 12 is formed at an outside of the lamp bead main body 1, and a second inclined surface 51 is formed inside the mask 5. The second inclined surface 51 has a same inclination direction as the first inclined surface 12, and the inclined section 61 is formed between the first inclined surface 12 and the second inclined surface 51. Where the first inclined surface 12 may or may not be parallel to the second inclined surface 51. When forming the lamp bead main body 1 through injection molding, an inclination angle of the injection mold can be adjusted to increase an inclination angle of an outer wall of the lamp bead main body 1, so that the first inclined surface 12 extends from bottom to top towards a center of the lamp bead main body 1, thereby reducing an area of the lamp bead main body 1 on the light emitting surface 11 and forming a narrow cup mouth, which can greatly improve a brightness of the lamp bead and enhance an display effect. Meanwhile, the second inclined surface 51 can also extend obliquely from bottom to top towards the center of the lamp bead main body 1, allowing the narrow cup mouth lamp bead main body 1 to be matched with a special mask 5, which can increase an overall contrast. In this embodiment, a design of the mask 5 can improve a surface consistency and enhance a surface blackness of the display module when the lamp bead forms the display module.

In an implementation mode, the first inclined surface 12 is configured to be parallel to the second inclined surface 51. Compared to a non-parallel arrangement of the first inclined surface 12 and the second inclined surface 51, this embodiment sets them to be parallel, which allows the cover 5 to be more easily inserted between two adjacent lamp bead main bodies 1.

As shown in FIG. 3, in one embodiment, the gap 6 may further include a vertical section 62, which is connected to the inclined section 61. Compared to the inclined section 61, the vertical section 62 is biased away from the light emitting surface 11. Where, the vertical section 62 extends vertically in an up-down direction, while the inclined section 61 extends obliquely relative to the vertical section 62. At a position where the vertical section 62 is formed, an outer wall surface of the lamp bead main body 1 is vertical, and an inner wall surface of the mask 5 is also vertical. Compared with the gap 6 that is completely configured to be inclined, in this embodiment, a part of the gap 6 is configured to be the vertical section 62, which not only facilitates a manufacturing of the lamp bead main body 1 and the mask 5, but also shortens a width of the lamp bead main body 1 in a horizontal direction, thereby reducing a size of the lamp bead.

Of course, in other embodiments, the gap 6 can be configured to be the inclined section 61 as a whole, or the gaps 6 can also include a curved section and other structures, without limitation here.

In an implementation mode, as shown in FIG. 3, the vertical section 62 is filled with the colloform 9, and at least a part of the colloform 9 extends into the inclined section 61. In this embodiment, the colloform 9 located in the vertical section 62 can fix the lamp bead main body 1 and the mask 5 together. The colloform 9 located in a lower position of the inclined section 61 can also be filled with the colloform 9. The colloform 9 located in the inclined section 61 is connected to the colloform 9 in the vertical section 62 as a whole. Since the inclined section 61 extends obliquely relative to the vertical section 62, the colloform 9 located in the inclined section 61 also extends obliquely relative to the colloform 9 in the vertical section 62. The colloform 9 inclined in the gap 6 can connect the mask 5 and the lamp bead main body 1 in different directions, which can further enhance a connection strength between the mask 5 and the lamp bead main body 1.

Of course, in other embodiments, the colloform 9 can also be filled only within the vertical section 62 as needed.

In an implementation mode, a range for an angle between the inclined section 61 and the light emitting surface 11 is 50°-75°, which means that an inclination angle of the inclined section 61 relative to the vertical plane is 15°-40°, in an implementation mode, 20°. The inclination angle of an outer side of a traditional lamp bead main body is only 5°-10°. Due to a small inclination angle of a cup mouth and a vertical design of the inner wall of the mask 5, there is a vertical gap between the lamp bead main body 1 and the mask 5 (i.e. the gap extends vertically in the up-down direction). When viewed from the front, the bottom surface of the gap 6 can be seen, which may expose a bottom material and affect the front display effect.

As shown in FIG. 2, embodiments of the present application further provide a lamp bead, which includes a lamp bead main body 1, the lamp bead main body 1 is provided with at least two anode solder pads 2, and the lamp bead main body 1 is installed with at least three light-emitting chips 4, where an anode of one of the light-emitting chips 4 is electrically connected to one of the anode solder pads 2, and anodes of at least two other light-emitting chips 4 are electrically connected to another of the anode solder pads 2. The lamp bead provided in this embodiment can adopt any lamp bead provided in the above embodiments of the display module, and will not be repeated here.

Embodiments of the present further provide a display module, including a plurality of lamp beads, and the lamp beads in this embodiment can adopt any of the lamp bead provided in the above embodiments, which will not be repeated here. In addition to the lamp beads, the display module in this embodiment may also include the aforementioned mask 5, which separates the plurality of lamp beads and forms the gap 6 between the mask 5 and the lamp beads.

In the description of the present application, it should be noted that terms “up”, “down”, etc. indicate an orientation or positional relationship based on an orientation or positional relationship shown in the accompanying drawings, only for a convenience of describing the present application and simplifying the description, and do not indicate or imply that the device or component referred to must have a specific orientation, be constructed and operated in a specific orientation, and therefore cannot be understood as a limitation of the present application. Unless otherwise specified and limited, terms “installation”, “connection to”, and “connection with” should be broadly understood, for example, they can be a fixed connection, a detachable connection, or an integral connection; it can be a mechanical connection or an electrical connection; it can be a direct connection, an indirect connection through an intermediate medium, or connected internally between two components. For those skilled in the art, a specific meaning of the above terms in the present application can be understood according to a specific situation.

It should be noted that in the present application, relationship terms such as “first” and “second” are only used to distinguish one entity or operation from another, and do not necessarily require or imply any such actual relationship or order between these entities or operations. Moreover, term “including”, “including”, or any other variation thereof are intended to encompass a non-exclusive inclusion, such that a process, method, item, or device that includes a series of elements includes not only those elements, but also other elements not explicitly listed, or elements inherent to such process, method, item, or device. Without further limitations, the element defined by the statement “including one . . . ” does not exclude an existence of other identical elements in the process, method, item, or device that includes the element.

The above description is only a specific implementation mode of the present application, which enables those skilled in the art to understand or implement the present application. Various modifications to these embodiments will be apparent to those skilled in the art, and a general principle defined herein can be implemented in other embodiments without departing from the spirit or scope of the present application. Therefore, the present application will not be limited to the embodiments shown in this specification, but will conform to a widest scope consistent with the principle and novel features applied in this specification.

What is claimed is:

1. A display module, comprising:
a lamp bead main body, which is provided with at least two anode solder pads and at least three light-emitting chips, wherein an anode of one of the light-emitting chips is electrically connected to one of the anode solder pads, and anodes of at least two other light-emitting chips are electrically connected to another of the anode solder pads;
a mask, which is provided at an outside of the lamp bead main body, a gap is formed between the mask and the lamp bead main body; the gap comprises an inclined section, and the inclined section extends obliquely from a light emitting surface of the lamp bead main body towards a direction away from the light emitting surface and away from the lamp bead main body.

2. The display module according to claim 1, wherein the at least three light-emitting chips comprise a red-light chip, a blue-light chip, and a green-light chip, an anode of the red-light chip is electrically connected to one of the anode solder pads; anodes of the blue-light chip and the green-light chip are electrically connected to another of the anode solder pads.

3. The display module according to claim 1, wherein the lamp bead main body is provided with two anode solder pads and three light-emitting chips;
the lamp bead main body is further provided with two anode pins and three cathode pins, each of the anode solder pads is electrically connected to one of the anode pins, and a cathode of each of the light-emitting chips is electrically connected to one of the cathode pins.

4. The display module according to claim 2, wherein the lamp bead main body is provided with two anode solder pads and three light-emitting chips;
the lamp bead main body is further provided with two anode pins and three cathode pins, each of the anode solder pads is electrically connected to one of the anode pins, and a cathode of each of the light-emitting chips is electrically connected to one of the cathode pins.

5. The display module according to claim 3, wherein the lamp bead main body is further provided with a dummy pin, the dummy pin with the two anode pins and the three cathode pins are symmetrically distributed on the lamp bead main body.

6. The display module according to claim 4, wherein the lamp bead main body is further provided with a dummy pin, the dummy pin with the two anode pins and the three cathode pins are symmetrically distributed on the lamp bead main body.

7. The display module according to claim 1, wherein the gap is filled with a colloform, and at least a part of the inclined section is not filled with the colloform, thereby a clearance is formed between the colloform in the gap and the light emitting surface.

8. The display module according to claim 1, wherein a first inclined surface is formed at an outside of the lamp bead main body, and a second inclined surface is formed inside the mask;
the second inclined surface has a same inclination direction as the first inclined surface, and the inclined section is formed between the first inclined surface and the second inclined surface.

9. The display module according to claim 1, wherein the gap further comprises a vertical section connected to the inclined section, and relative to the inclined section, the vertical section is biased away from the light emitting surface.

10. The display module according to claim 9, wherein the vertical section is filled with the colloform, and at least a part of the colloform extends into the inclined section.

11. A lamp bead, comprising:
a lamp bead main body, which is provided with at least two anode solder pads and at least three light-emitting chips, wherein an anode of one of the light-emitting chips is electrically connected to one of the anode solder pads, and anodes of at least two other light-emitting chips are electrically connected to another of the anode solder pads.

12. A display module, comprises a plurality of lamp beads according to claim 11.
